(19) United States
(12) Patent Application Publication
(10) Pub. No.: US 2024/0297479 A1
(43) Pub. Date: Sep. 5, 2024

(54) OPTICAL SEMICONDUCTOR DEVICE

(71) Applicant: Mitsubishi Electric Corporation, Tokyo (JP)

(72) Inventors: Shogo ITO, Tokyo (JP); Keisuke MATSUMOTO, Tokyo (JP)

(73) Assignee: Mitsubishi Electric Corporation, Tokyo (JP)

(21) Appl. No.: 18/697,905

(22) PCT Filed: Oct. 19, 2021
(86) PCT No.: PCT/JP2021/038520

§ 371 Date: Apr. 2, 2024

(51) Int. Cl. H01S 5/024; H01S 5/026; H01S 5/042; H01S 5/062; H01S 5/20

(52) U.S. Cl. CPC H01S 5/02453; H01S 5/0268; H01S 5/04256; H01S 5/06246; H01S 5/2009

(57) ABSTRACT

An optical semiconductor comprises a semiconductor substrate and a semiconductor structure part including an optical waveguide layer that is formed on the semiconductor substrate. The semiconductor structure part includes a cladding layer connected to a first face that is the face on the side of the semiconductor substrate in the optical waveguide layer and to a second face that is the face on the opposite side of the semiconductor substrate, and a heater layer made of a semiconductor material to heat the optical waveguide layer from the side of the first face or/and from the side of the second face in the optical waveguide layer through the cladding layer.

### TECHNICAL FIELD

The present application relates to an optical semiconductor device.

### BACKGROUND ART

In an optical semiconductor device provided with an optical waveguide structure including an optical waveguide layer for guiding light, a heater layer for heating the optical waveguide layer is further included and the refractive index of the optical waveguide layer can be changed by changing the temperature of the optical waveguide layer. The optical semiconductor device including the optical waveguide layer and the heater layer can control the wavelength characteristic or phase of light propagating through the optical waveguide layer by changing the refractive index of the optical waveguide layer.

Patent Document 1 discloses a wavelength tunable semiconductor laser including a resistive heating film serving as a heater layer. The wavelength tunable semiconductor laser of Patent Document 1 includes an active region in which light is generated, a phase control region, and a distributed reflection region. In the phase control region and the distributed reflection region, an n-type cladding layer, an optical waveguide layer, a p-type cladding layer, and a p-side electrode are sequentially formed, and a resistive heating film is formed on the p-side electrode of each region through an insulating film. The resistive heating film in the phase control region and the resistive heating film in the distributed reflection region are separated from each other and independently heat the optical waveguide layer in each region. The phase control region is formed between the active region and the distributed reflection region, and by energizing the resistive heating film in the phase control region, the refractive index of the entire phase control region is changed by the heat. In the wavelength tunable semiconductor laser of Patent Document 1, the refractive index of the entire phase control region is controlled by the heat, and the phase of the light reflected by the distributed reflection region and the phase of the light of the resonator (the entire laser) are matched, thereby suppressing mode skipping during wavelength tuning.

### CITATION LIST

### Patent Document

Patent Document 1: Japanese Patent Application Laid-Open Publication No. H06-350203

### SUMMARY OF INVENTION

### Problems to be solved by Invention

In Patent Document 1, the material of the resistive heating film serving as the heater layer is Ti. As the material of the heater layer, a metallic material such as Ti, NiCr, or Pt is mainly used. These metallic materials are used because their resistivity is higher than that of Au and other metals used in conductor wiring, allowing the heater layer to generate more heat than the conductor wiring. However, when a metallic material is used for the heater layer, a process of forming the heater layer and a process of forming an electrode of the heater layer are required after a semiconductor structure part including the n-type cladding layer, the optical waveguide layer, and the p-type cladding layer is formed and the p-side electrode is formed on the top surface of the semiconductor structure part as in the wavelength tunable semiconductor laser of Patent Document 1. That is, in the case where a metallic material is used for the heater layer, the step of forming the semiconductor structure part and the step of forming the heater layer cannot be continuously performed, so that the manufacturing period of time of the optical semiconductor device becomes long.

It is an object of the technology disclosed in the specification of the present application to provide an optical semiconductor device including a heater layer in which a conventional semiconductor structure part and a heater layer can be continuously formed and a manufacturing period of time can be shortened more than before.

### Means for solving Problems

An example of an optical semiconductor device disclosed in the specification of the present application includes a semiconductor substrate and a semiconductor structure part including an optical waveguide layer that is formed on the semiconductor substrate. The semiconductor structure part includes a cladding layer connected to a first face that is a face on a side of the semiconductor substrate, and to a second face that is a face on an opposite side of the semiconductor substrate, in the optical waveguide layer, and a heater layer made of a semiconductor material to heat the optical waveguide layer from a side of the first face or/and from a side of the second face in the optical waveguide layer through the cladding layer.

### Effect of Invention

An example of an optical semiconductor device disclosed in the present specification includes the optical waveguide layer and the heater layer made of a semiconductor material for heating the optical waveguide layer from the side of the first face or/and from the side of the second face in the optical waveguide layer through the cladding layer, and the semiconductor structure part including the heater layer can be formed, so that the conventional semiconductor structure part and the heater layer can be formed continuously, and the manufacturing period of time can be shortened more than before.

### BRIEF DESCRIPTION OF DRAWINGS

FIG. 1 is a perspective view showing an optical semiconductor device according to Embodiment 1.

FIG. 2 is a plan view of the optical semiconductor device of FIG. 1.

FIG. 3 is a cross-sectional view taken along a broken line indicated by A-A in FIG. 2.

FIG. 4 is a cross-sectional view taken along a broken line B-B in FIG. 2.

FIG. 5 is a diagram showing an end face of another optical semiconductor device according to Embodiment 1.

FIG. 6 is a perspective view showing an optical semiconductor device according to Embodiment 2.

FIG. 7 is a plan view of the optical semiconductor device of FIG. 6.

FIG. 8 is a cross-sectional view taken along a broken line C-C in FIG. 7.

FIG. 9 is a cross-sectional view taken along a broken line D-D in FIG. 7.

FIG. 10 is a perspective view showing an optical semiconductor device according to Embodiment 3.

FIG. 11 is a plan view of the optical semiconductor device of FIG. 10.

FIG. 12 is a diagram showing an end face of the optical semiconductor device of FIG. 10.

FIG. 13 is a perspective view showing an optical semiconductor device according to Embodiment 4.

FIG. 14 is a plan view of the optical semiconductor device of FIG. 13.

FIG. 15 is a diagram showing an end face of the optical semiconductor device of FIG. 13.

FIG. 16 is a perspective view showing an optical semiconductor device according to Embodiment 5.

FIG. 17 is a diagram showing an end face of the optical semiconductor device of FIG. 16.

FIG. 18 is a perspective view showing another optical semiconductor device according to Embodiment 5.

FIG. 19 is a diagram showing an end face of the optical semiconductor device of FIG. 18.

FIG. 20 is a diagram showing an optical semiconductor device according to Embodiment 6.

FIG. 21 is a perspective view showing an optical processing section of FIG. 20.

FIG. 22 is a plan view of the optical processing section of FIG. 20.

FIG. 23 is a cross-sectional view taken along a broken line indicated by E-E in FIG. 22.

### MODE FOR CARRYING OUT INVENTION

### Embodiment 1

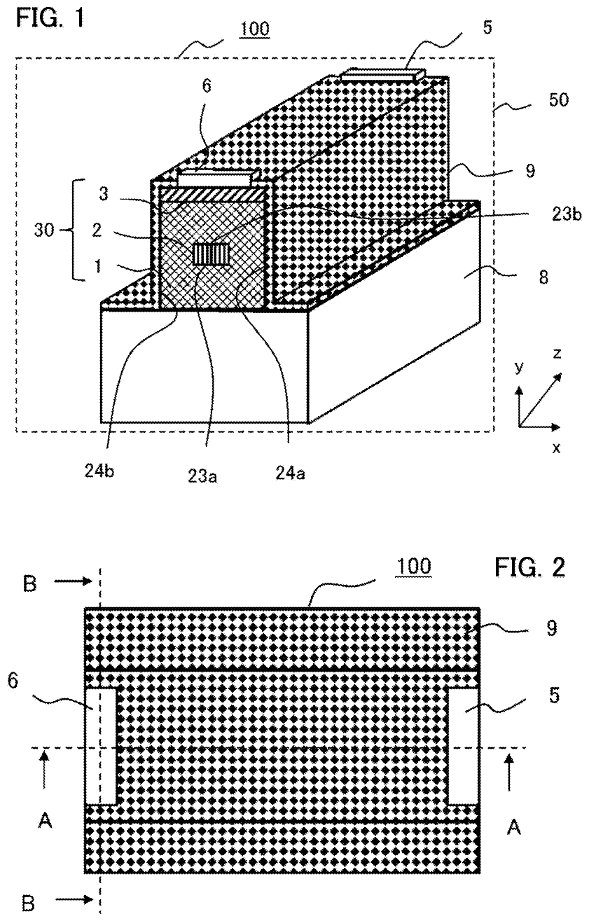

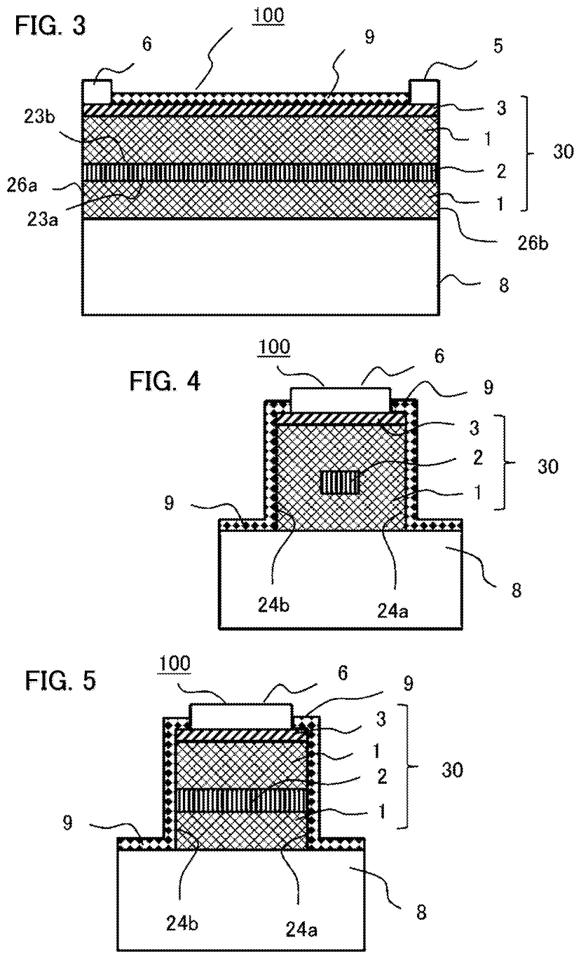

FIG. 1 is a perspective view showing an optical semiconductor device according to Embodiment 1, and FIG. 2 is a plan view of the optical semiconductor device of FIG. 1. FIG. 3 is a cross-sectional view taken along a broken line indicated by A-A in FIG. 2, and FIG. 4 is a cross-sectional view taken along a broken line indicated by B-B in FIG. 2. FIG. 5 is a diagram showing an end face of another optical semiconductor device according to Embodiment 1. In Embodiment 1, a phase adjuster 50 will be described as an example of an optical semiconductor device 100. The phase adjuster 50 includes a semiconductor substrate 8 and a semiconductor structure part 30 including an optical waveguide layer 2 that is formed on the semiconductor substrate 8. The semiconductor structure part 30 includes the optical waveguide layer 2 to guide light, a cladding layer 1 connected to a first face 23a that is a face on the side of the semiconductor substrate, to a second face 23b that is a face on the opposite side of the semiconductor substrate 8 in the optical waveguide layer 2, and a heater layer 3 made of a semiconductor material for heating the optical waveguide layer 2 from the side of the second face 23b of the optical waveguide layer 2 through the cladding layer 1.

The semiconductor structure part 30 has a mesa shape including a first side face 24a and a second side face 24b that are opposed to each other with the optical waveguide layer 2 interposed therebetween, the optical waveguide layer extending in a z-direction. Further, the semiconductor structure part 30 includes a first end face 26a and a second end face 26b that intersect with the extending direction of the optical waveguide layer 2 and are opposed to each other. The semiconductor structure part 30 has a width in a x-direction perpendicular to the z-direction to be smaller than a width of the semiconductor substrate 8 in the x-direction, and protrudes from the semiconductor substrate 8 in a y-direction perpendicular to the z-direction and the y-direction. FIG. 1 to FIG. 4 illustrate an example in which the semiconductor structure part 30 is disposed in the central portion of the semiconductor substrate 8 in the x-direction. For example, the first end face 26a is an end face on the negative side in the z-direction, the second end face 26b is an end face on the positive side in the z-direction, the first side face 24a is a side face on the positive side in the x-direction, and the second side face 24b is a side face on the negative side in the x-direction.

The heater layer 3 is provided with two electrodes for energizing the heater layer 3, i.e., a power supply electrode 5 and a ground electrode 6. FIG. 1 illustrates an example in which the ground electrode 6 is provided as a first electrode on the side of the first end face in the heater layer 3, and the power supply electrode 5 is provided as a second electrode on the side of the second end face in the heater layer 3. The distance from the top surface of the semiconductor structure 30, i.e., the surface of the semiconductor structure part 30 at its farthest distance from the semiconductor substrate 8, to the second face 23b of the optical waveguide layer 2 is, for example, about 3 μm. In addition, the distance from the first face 23a of the optical waveguide layer 2 to the substrate 8 is, for example, about 3 μm. Also, the height of the semiconductor structure part 30 in the y-direction is, for example, about 10 μm. The thickness of the optical waveguide layer 2 in the y-direction is, for example, about 4 μm. As appropriate, a surface on the positive side in the y-direction is represented as a top surface. The plan view of FIG. 2 is a diagram showing the top surface of the optical semiconductor device 100.

The semiconductor substrate 8 is, for example, a substrate made of InP. An insulating film 9 such as SiO₂ functioning as a protective film is formed on the top surface of the semiconductor structure part 30, the first side face 24a,the second side face 24b,and exposed surfaces of the semiconductor substrate 8 on the side where the semiconductor structure part 30 is formed. After openings are formed on the side of the first end face and the side of the second end face in the insulating film 9, the power supply electrode 5 and the ground electrode 6 are formed. The power supply electrode 5 and the ground electrode 6 are made of a conductive material such as Au.

A material of the cladding layer 1 is, for example, InP. The cladding layer 1 has a function of confining light such as laser light propagating through the optical waveguide layer 2. The material of the optical waveguide layer 2 is, for example, a material having a wavelength of an absorption edge on the shorter wavelength side than the incident light oscillation wavelength, and the optical waveguide layer 2 is made of, for example, an InGaAsP-based crystal. Here, the absorption edge is a wavelength at which an absorption coefficient of light propagating through the optical waveguide layer 2 steeply rises or falls in the spectrum that is shown with the horizontal axis representing the wavelength of light and the vertical axis representing the absorption coefficient.

The material of the heater layer 3 is, for example, a semiconductor material such as InGaAs, which generates heat in response to supplied power and is substantially lattice-matched with the cladding layer 1 and the optical waveguide layer 2. In addition, the material of the heater layer 3 is a material that can be also applied to a contact layer 4 for flowing a current to the cladding layer 1 in Embodiment 6 to be described later. The heater layer 3 is, for example, n-type InGaAs (n-InGaAs) doped with sulfur (S), and has a sheet resistance of about 3.2 Ω when the carrier concentration of sulfur is 8.0×10¹⁸ cm⁻³. In this case, when the heater layer 3 has a width of 2 μm in the x-direction, a thickness of 0.4 μm in the y-direction, and a length of 50 μm in the z-direction, the heater layer 3 is a resistive thin film of about 200 Ω.

The heater layer 3 has a lower resistivity than the cladding layer 1. The resistivity of the heater layer 3 and the resistivity of the cladding layer 1 are, for example, as follows. When the heater layer 3 is made of n-InGaAs doped with sulfur having a carrier concentration of 8.0×10¹⁸ cm⁻³, the resistivity of the heater layer 3 is about 3.2 Ω·μm. When the cladding layer 1 is made of, for example, n-InP doped with sulfur having a carrier concentration of 1.0×10¹⁹ cm⁻³, the resistivity of the cladding layer 1 is about 6.0 Ω·μm. The heater layer 3 may be made of p-type InGaAs (p-InGaAs) doped with zinc (Zn), and the cladding layer 1 may be made of p-type InP (p-InP) doped with zinc. When the heater layer 3 is made of p-InGaAs doped with zinc having a carrier concentration of 1.5×10¹⁹ cm⁻³, the resistivity of the heater layer 3 is about 64 Ω·μm. When the cladding layer 1 is made of, for example, p-InP doped with zinc having a carrier concentration of 2.0×10¹⁹ cm⁻³, the resistivity of the cladding layer 1 is about 400 Ω·μm. Even when the heater layer 3 and the cladding layer 1 are made of p-type, the heater layer 3 has a lower resistivity than the cladding layer 1.

The phase adjuster 50, which is an example of the optical semiconductor device 100 of Embodiment 1, changes the refractive index of the optical waveguide layer 2 by the thermo-optic effect due to the heat generated by the heater layer 3, and adjusts the phase of the light propagating through the optical waveguide layer 2. The phase adjuster 50 of Embodiment 1 can be applied to such a case where it is necessary to adjust the phase of light propagating through the optical waveguide layer 2 with high accuracy. For example, a modulator including a Mach-Zehnder waveguide structure to be described later, that is, a Mach-Zehnder modulator modulates input light by utilizing the fact that when the phase difference between light in two arms satisfies nπ (n is 0 or an even number), light in the two arms strengthen each other when they are multiplexed, and when the phase difference between light in the two arms satisfies kπ (k is an odd number), light in the two arms cancel each other when they are multiplexed. By adjusting the phases of the light of the two arms with high accuracy, it is possible to improve an extinction ratio of the output light obtained by multiplexing the light of the two arms. The extinction ratio is the ratio of the intensity of the light intensified to that cancelled out. By improving the extinction ratio of the output light, high-speed modulation can be performed.

In the phase adjuster 50 of Embodiment 1, the heater layer 3 can be formed in the step of forming the semiconductor structure part 30 on the semiconductor substrate 8. The step of forming the semiconductor structure part 30 includes a step of forming the cladding layer 1 below the optical waveguide layer 2, that is, a lower cladding layer on the side of the semiconductor substrate 8, a step of forming the optical waveguide layer 2 on the top surface of the lower cladding layer 1, a step of forming an upper cladding layer 1 covering surfaces of the optical waveguide layer 2 (the surface on the positive side in the y-direction, the side surface on the positive side in the x-direction, the side surface on the negative side in the x-direction), and a step of forming the heater layer 3 on the top surface of the upper cladding layer 1. The method of manufacturing the phase adjuster 50 of Embodiment 1 is different from the laser manufacturing method of Patent Document 1 that requires the step of forming the heater layer made of a metallic material and the step of forming an electrode of the heater layer after forming a semiconductor structure part (conventional semiconductor structure part) including the n-type cladding layer, the optical waveguide layer, and the p-type cladding layer and forming the p-side electrode on the top surface of the semiconductor structure, and the step of forming the heater layer in the method of Embodiment 1 is included in the step of forming the semiconductor structure part 30. Therefore, the method of manufacturing the phase adjuster 50 of Embodiment 1 can eliminate the process of forming the heater layer made of the metallic material on the top surface of the semiconductor structure part, and can shorten the manufacturing period of time as compared with the manufacturing process of the laser of Patent Document 1. Further, the manufacturing method for the laser of Patent Document 1 requires a film forming apparatus for forming the heater layer made of the metallic material such as Ti, but the method of manufacturing the phase adjuster 50 of Embodiment 1 can eliminate the film forming apparatus for forming the heater layer made of a metallic material such as Ti. The phase adjuster 50 of Embodiment 1 can shorten the manufacturing period of time as compared with the manufacturing process of the laser of Patent Document 1, and can eliminate the film forming apparatus for forming the heater layer made of a metallic material such as Ti, so that the manufacturing cost can be reduced.

Compared with a process of forming the semiconductor structure part 30 made of a semiconductor material, that is, a dry etching processing technique in a semiconductor process, in the case where the heater layer made of a metallic material is formed by an etching processing technique such as milling or wet etching that is inferior in processing accuracy, the heater layer made of the metallic material is not stable in its shape, and it is difficult to control the resistance value related to the heater operation. In contrast, in the phase adjuster 50 of Embodiment 1, since the heater layer 3 is made of a semiconductor material, it is possible to improve the processing accuracy of the heater layer 3 by dry etching or the like in the semiconductor process, and it is possible to reduce the resistance value deviation due to the shape variation of the heater layer 3.

Unlike the laser of Patent Document 1, the phase adjuster 50 of Embodiment 1 does not require to form an insulating film such as SiO₂ between the heater layer and the optical semiconductor structure part, so that the optical waveguide layer 2 can be heated from inside the semiconductor structure part 30, and the thermal efficiency in heating the optical waveguide layer 2 by the heater layer 3 can be improved.

As shown in FIG. 5, the width of the optical waveguide layer 2 may be the same as the width of the semiconductor structure part 30 in the x-direction. In this case, since the dry etching process for processing the optical waveguide layer 2 can be eliminated as compared with the phase adjuster 50 shown in FIG. 1, the manufacturing period of time can be shortened as compared with the phase adjuster 50 shown in FIG. 1. Although the example in which the semiconductor structure part 30 has a mesa shape has been described, the semiconductor structure part 30 may not have a mesa shape. That is, the width of the semiconductor structure part 30 in the z-and x-direction may be the same as the width of the semiconductor substrate 8 in the x-direction.

As described above, the optical semiconductor device 100 of Embodiment 1 is provided with the semiconductor substrate 8 and the semiconductor structure part 30 including the optical waveguide layer 2 that is formed on the semiconductor substrate 8. The semiconductor structure part 30 includes the cladding layer 1 connected to the first face 23a that is the face on the side of the semiconductor substrate, and to the second face 23b that is the face on the opposite side of the semiconductor substrate 8, in the optical waveguide layer 2, and the heater layer 3 made of a semiconductor material to heat the optical waveguide layer 2 from the side of the second face in the optical waveguide layer 2 through the cladding layer 1. With this configuration, the optical semiconductor device 100 of Embodiment 1 includes the optical waveguide layer 2 and the heater layer 3 made of a semiconductor material for heating the optical waveguide layer 2 from the side of the second face of the optical waveguide layer 2 through the cladding layer 1, and the semiconductor structure part 30 including the heater layer 3 can be formed, so that the conventional semiconductor structure part and the heater can be continuously formed and the manufacturing period of time can be shortened more than before.

### Embodiment 2

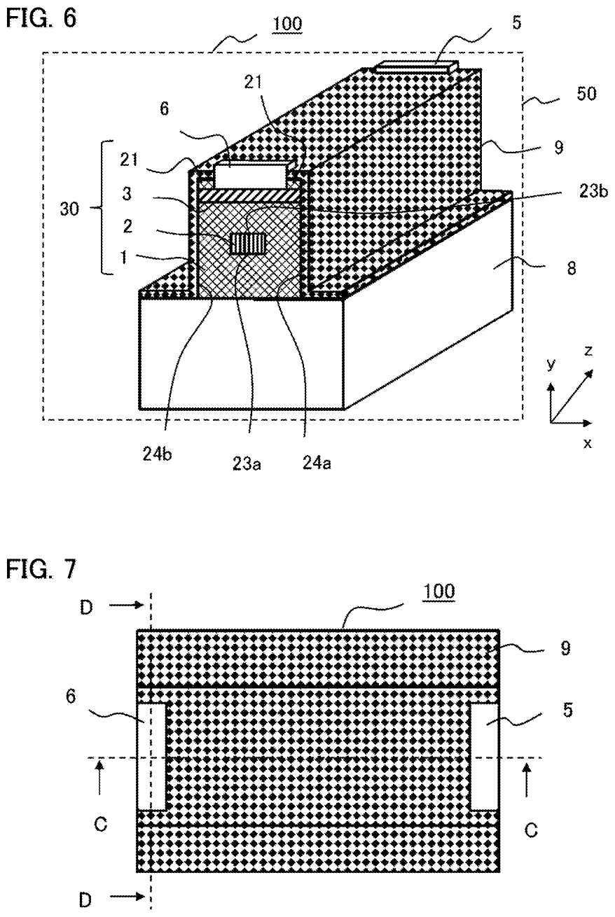

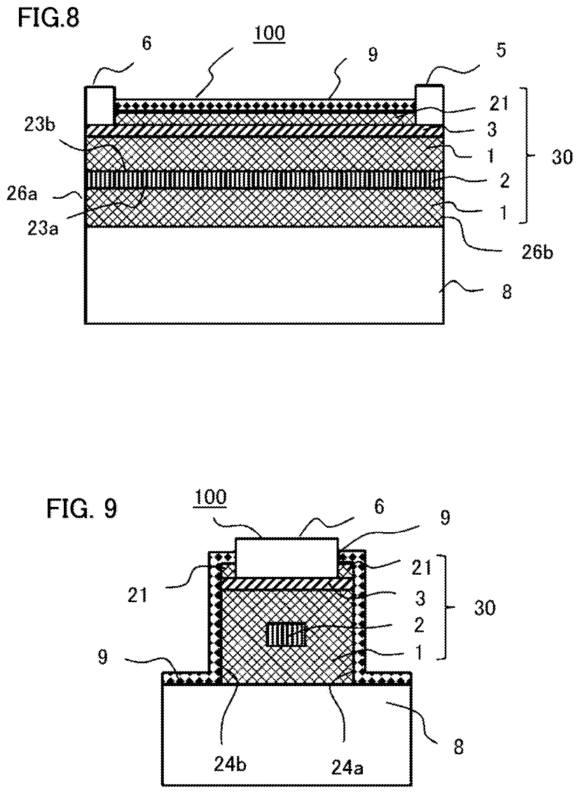

FIG. 6 is a perspective view showing an optical semiconductor device according to Embodiment 2, and FIG. 7 is a plan view of the optical semiconductor device of FIG. 6. FIG. 8 is a cross-sectional view taken along a broken line C-C in FIG. 7, and FIG. 9 is a cross-sectional view taken along a broken line D-D in FIG. 7. A phase adjuster 50, which is an example of the optical semiconductor device 100 of Embodiment 2, is different from the optical semiconductor device 100 of Embodiment 1 in that the semiconductor structure part 30 includes the cladding layer 1, the optical waveguide layer 2, the heater layer 3, and a cladding layer 21. Differences from the optical semiconductor device 100 of Embodiment 1 will be mainly described.

In the semiconductor structure part 30 of Embodiment 2, the cladding layer 21 is formed on the top surface of the heater layer 3. The insulating film 9 such as SiO₂ functioning as a protective film is formed on the top surface of the semiconductor structure part 30, the first side face 24a,the second side face 24b,and the exposed surfaces of the semiconductor substrate 8 on the side where the semiconductor structure part 30 is formed. After openings are formed in the insulating film 9 and the cladding layer 21 on the side of the first end face and the side of the second end face, the power supply electrode 5 and the ground electrode 6 are formed.

In the optical semiconductor device 100 of Embodiment 2, the cladding layer 21 is formed on the top surface of the heater layer 3, and in the case where the height of the semiconductor structure part 30 in the y-direction is made the same as that of the semiconductor structure part 30 of Embodiment 1, the distance between the heater layer 3 and the second face 23b of the optical waveguide layer 2 can be reduced, so that the temperature of the optical waveguide layer 2 can be efficiently controlled. Therefore, the optical semiconductor device 100 of Embodiment 2 can control the phase of the incident light propagating through the optical waveguide layer 2 more efficiently than the optical semiconductor device 100 of Embodiment 1.

In the optical semiconductor device 100 of Embodiment 2, since the cladding layer 21 is formed on the top surface of the heater layer 3, it is possible to reduce the distance between the heater layer 3 and the second face 23b of the optical waveguide layer 2 while the height of the semiconductor structure part 30 in the y-direction is kept at a predetermined height, so that the temperature of the optical waveguide layer 2 can be efficiently controlled. Further, even in a case where the thickness of the heater layer 3 is set to a predetermined thickness, it is possible to reduce the distance between the heater layer 3 and the second face 23b of the optical waveguide layer 2 while the height of the semiconductor structure part 30 in the y-direction is kept at a predetermined height, so that the temperature of the optical waveguide layer 2 can be efficiently controlled. In a case where an optical element other than the phase adjuster 50 is formed in the optical semiconductor device 100, by matching the height in the y-direction of the semiconductor structure part 30 in the phase adjuster 50 and the height of the optical element in the y-direction, it is possible to improve the resist coating property by the photolithography technique performed in a process after the film formation of each layer of the semiconductor structure part 30.

As in the optical semiconductor device 100 of Embodiment 1, the optical semiconductor device 100 of Embodiment 2 includes the optical waveguide layer 2 and the heater layer 3 made of a semiconductor material for heating the optical waveguide layer 2 from the side of the first face of the optical waveguide layer 2 through the cladding layer 1, and the semiconductor structure part 30 including the heater layer 3 can be formed, so that the conventional semiconductor structure part and the heater can be continuously formed and the manufacturing period of time can be shortened more than before.

### Embodiment 3

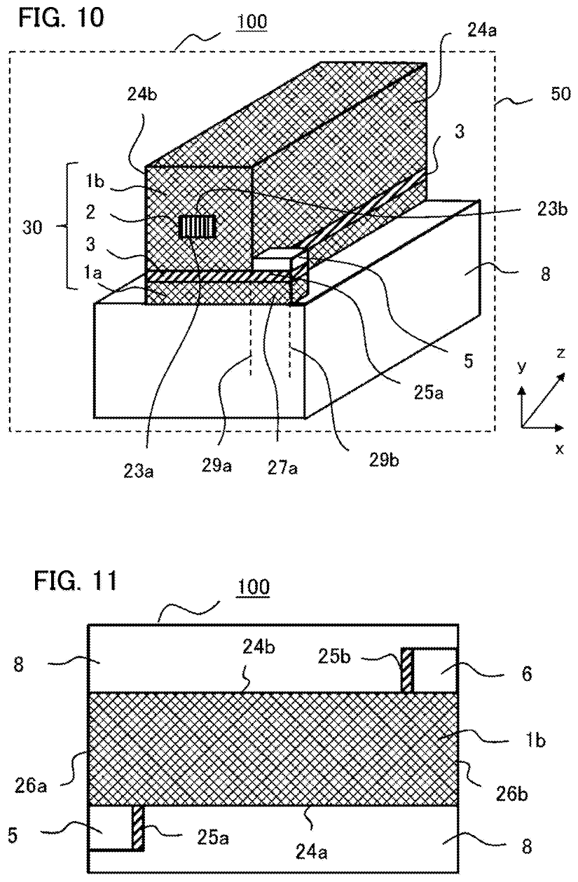

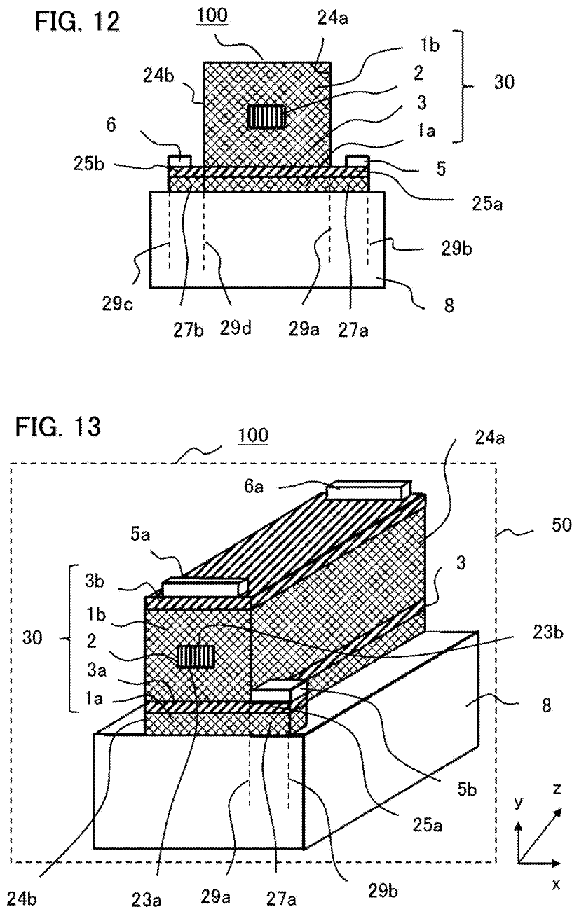

FIG. 10 is a perspective view showing an optical semiconductor device according to Embodiment 3, and FIG. 11 is a plan view of the optical semiconductor device of FIG. 10. FIG. 12 is a diagram showing an end face of the optical semiconductor device of FIG. 10. A phase adjuster 50, which is an example of the optical semiconductor device 100 of Embodiment 3, differs from the optical semiconductor device 100 of Embodiment 1 in that the semiconductor structure part 30 includes a cladding layer 1a, the heater layer 3, a cladding layer 1b, and the optical waveguide layer 2. Differences from the optical semiconductor device 100 of Embodiment 1 will be mainly described. Note that, in FIG. 10, FIG. 11, and FIG. 12, the insulating film 9 is omitted.

In the semiconductor structure part 30 of Embodiment 3, the heater layer 3 is provided on the side of the first face 23a of the optical waveguide layer 2. The cladding layer 1a is formed on the top surface of the substrate 8, and the heater layer 3 is formed on the top surface of the cladding layer 1a. The cladding layer 1b and the optical waveguide layer 2 are formed on the top surface of the heater layer 3. The step of forming the semiconductor structure part 30 includes a step of forming the cladding layer 1a, a step of forming the heater layer 3 on the top surface of the cladding layer 1a, a step of forming the cladding layer 1b below the optical waveguide layer 2, that is, a lower cladding layer on the side of the semiconductor substrate 8, a step of forming the optical waveguide layer 2 on the top surface of the lower cladding layer 1b, and a step of forming an upper cladding layer 1b covering the surfaces of the optical waveguide layer 2 (the surface on the positive side in the y-direction, the side surface on the positive side in the x-direction, the side surface on the negative side in the x-direction).

A first extending portion 25a of the heater layer 3 and a first extending portion 27a of the cladding layer 1a, which extend from the first side face 24a in a direction away from the optical waveguide layer 2, are formed in the first side face 24a on the side of the first end face 26a in the semiconductor structure part 30. In addition, a second extending portion 25b of the heater layer 3 and a second extending portion 27b of the cladding layer la, which extend from the second side face 24b in a direction away from the optical waveguide layer 2, are formed in the second side face 24b on the side of the second end face 26b in the semiconductor structure part 30. The portions from a broken line 29a to a broken line 29b are the first extending portion 25a and the first extending portion 27a, and the portions from a broken line 29c to a broken line 29d are the second extending portion 25b and the second extending portion 27b. The broken line 29a is a broken line passing through the first side face 24a in the y-direction, and the broken line 29d is a broken line passing through the second side face 24b in the y-direction. FIG. 10 to FIG. 12 illustrate an example in which the mesa shape from the first side face 24a to the second side face 24b of the semiconductor structure part 30 is disposed in the central portion of the substrate 8 in the x-direction.

On the side of the first end face 26a of the semiconductor structure part 30, the first extending portion 25a of the heater layer 3 and the first extending portion 27a of the cladding layer 1a are formed on the side of the semiconductor substrate 8. Therefore, the width of the area in the x-direction where the first extending portion 25a and the first extending portion 27a are also formed is larger than the width from the first side face 24a to the second side face 24b in the x-direction and smaller than the width of the semiconductor substrate 8 in the x-direction. Similarly, on the side of the second end face 26b of the semiconductor structure part 30, the second extending portion 25b of the heater layer 3 and the second extending portion 27b of the cladding layer 1a are formed on the side of the semiconductor substrate 8 Therefore, the width of the area in the x-direction where the second extending portion 25b and the second extending portion 27b are also formed is larger than the width from the first side face 24a to the second side face 24b in the x-direction and smaller than the width of the semiconductor substrate 8 in the x-direction.

When the portion from the first side face 24a to the second side face 24b in the semiconductor structure part 30 is referred to as a mesa main portion, the first extending portion 25a and the first extending portion 27a on the side of the first end face 26a in the semiconductor structure part 30 can be referred to as a first mesa extending portion, and the second extending portion 25b and the second extending portion 27b on the side of the second end face 26b in the semiconductor structure part 30 can be referred to as a second mesa extending portion. The first mesa extending portion on the side of the first end face 26a of the semiconductor structure part 30 and the second mesa extending portion on the side of the second end face 26b of the semiconductor structure part 30 are arranged at symmetrical positions in the x-direction and the z-direction with the mesa main portion interposed therebetween. The power supply electrode 5 is provided as the first electrode on the first extending portion 25a of the heater layer 3, and the ground electrode 6 is provided as the second electrode on the second extending portion 25b of the heater layer 3. Since the first mesa extending portion and the second mesa extending portion are provided at the symmetrical positions with the mesa main portion interposed therebetween, a current can be efficiently supplied to the heater layer 3 as compared with a case where the first mesa extending portion and the second mesa extending portion are provided only on one side of the mesa main portion.

In the optical semiconductor device 100 of Embodiment 3, since the heater layer 3 is made of a semiconductor material, the heater layer 3 can be provided between the optical waveguide layer 2 and the semiconductor substrate 8 inside the semiconductor structure part 30 even when the heater layer 3 cannot be provided above the optical waveguide layer 2 in order to provide another function, etc.

As described above, the optical semiconductor device 100 of Embodiment 3 is provided with the semiconductor substrate 8 and the semiconductor structure part 30 including the optical waveguide layer 2 that is formed on the semiconductor substrate 8. The semiconductor structure part 30 includes the cladding layer 1 connected to the first face 23a that is the face on the side of the semiconductor substrate, and to the second face 23b that is the face on the opposite side of the semiconductor substrate 8, in the optical waveguide layer 2, and the heater layer 3 made of a semiconductor material to heat the optical waveguide layer 2 from the side of first face of the optical waveguide layer 2 through the cladding layer 1. The semiconductor structure part 30 is provided with the first side face 24a and the second side face 24b opposed to each other with the optical waveguide layer 2 interposed therebetween, and the first end face 26a and the second end face 26b that intersect with the extending direction of the optical waveguide layer 2 and are opposed to each other. The heater layer 3 includes the first extending portion 25a extending from the first side face 24a on the side of the first end face in the semiconductor structure part 30 in the direction away from the optical waveguide layer 2 and the second extending portion 25b extending from the second side face 24b on the side of the second end face in the semiconductor structure part 30 in the direction away from the optical waveguide layer 2. The power supply electrode 5 is provided as the first electrode on the first extending portion 25a of the heater layer 3, and the ground electrode 6 is provided as the second electrode on the second extending portion 25b of the heater layer 3. With this configuration, the optical semiconductor device 100 of Embodiment 3 includes the optical waveguide layer 2 and the heater layer 3 made of a semiconductor material for heating the optical waveguide layer 2 from the side of the first face of the optical waveguide layer 2 through the cladding layer 1, and the semiconductor structure part 30 including the heater layer 3 can be formed, so that the conventional semiconductor structure part and the heater layer can be continuously formed, and the manufacturing period of time can be shortened more than before.

### Embodiment 4

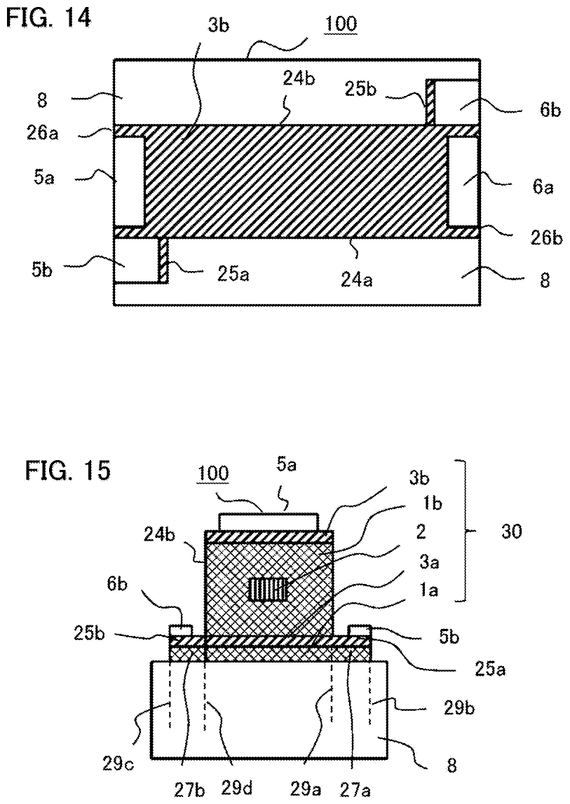

FIG. 13 is a perspective view showing an optical semiconductor device according to Embodiment 4, FIG. 14 is a plan view of the optical semiconductor device of FIG. 13, and FIG. 15 is a diagram showing an end face of the optical semiconductor device of FIG. 13.

A phase adjuster 50, which is an example of the optical semiconductor device 100 of Embodiment 4, is different from the optical modulator 100 of Embodiment 3 in that the semiconductor structure part 30 includes the cladding layer 1a, a heater layer 3a, the cladding layer 1b, the optical waveguide layer 2, and a heater layer 3b. Differences from the optical semiconductor device 100 of Embodiment 3 will be mainly described. Note that the insulating film 9 is omitted in FIG. 13, FIG. 14, and FIG. 15.

In the semiconductor structure part 30 of Embodiment 4, heater layers are provided on the side of the first face 23a and on the side of the second face 23b of the optical waveguide layer 2. The heater layer on the side of the first face 23a of the optical waveguide layer 2 is the heater layer 3a, and the heater layer on the side of the second face 23b of the optical waveguide layer 2 is the heater layer 3b. The cladding layer 1a is formed on the top surface of the substrate 8, and the heater layer 3a is formed on the top surface of the cladding layer 1a. The cladding layer 1b and the optical waveguide layer 2 are formed on the top surface of the heater layer 3a. The step of forming the semiconductor structure part 30 includes a step of forming the cladding layer 1a, a step of forming the heater layer 3a on the top surface of the cladding layer 1a, a step of forming the cladding layer 1b below the optical waveguide layer 2, that is, a lower layer on the side of the semiconductor substrate 8, a step of forming the optical waveguide layer 2 on the top surface of the cladding layer 1b of the lower layer, a step of forming the cladding layer 1b of an upper layer covering the surfaces of the optical waveguide layer 2(the surface on the positive side in the y-direction, the side surface on the positive side in the x-direction, the side surface on the negative side in the x-direction), and a step of forming the heater layer 3b on the top surface of the cladding layer 1b.

In the first side face 24a on the side of the first end face 26a in the semiconductor structure part 30, the first extending portion 25a of the heater layer 3a and the first extending portion 27a of the cladding layer 1a are formed to extend from the first side face 24a in a direction away from the optical waveguide layer 2. In addition, in the second side face 24b on the side of the second end face 26b in the semiconductor structure part 30, the second extending portion 25b of the heater layer 3a and the second extending portion 27b of the cladding layer 1a are formed to extend from the second side face 24b in a direction away from the optical waveguide layer 2. The portions from the broken line 29a to the broken line 29b are the first extending portion 25a and the first extending portion 27a, and the portions from the broken line 29c to the broken line 29d are the second extending portion 25b and the second extending portion 27b. The broken line 29a is a broken line passing through the first side face 24a in the y-direction, and the broken line 29d is a broken line passing through the second side face 24b in the y-direction. FIG. 13 to FIG. 15 illustrate an example in which the mesa shape from the first side face 24a to the second side face 24b of the semiconductor structure part 30 is disposed in the central portion of the substrate 8 in the x-direction.

On the side of the first end face 26a of the semiconductor structure part 30, the first extending portion 25a of the heater layer 3a and the first extending portion 27a of the cladding layer 1a are formed on the side of the semiconductor substrate 8. On the side of the second end face 26b of the semiconductor structure part 30, the second extending portion 25b of the heater layer 3a and the second extending portion 27b of the cladding layer 1a are formed on the side of the semiconductor substrate 8. Therefore, as in the optical semiconductor device 100 of Embodiment 3, the width of the area in the x-direction where the first extending portion 25a and the first extending portion 27a are also formed is larger than the width from the first side face 24a to the second side face 24b in the x-direction and smaller than the width of the semiconductor substrate 8 in the x-direction. Further, the width of the area in the x-direction where the second extending portion 25b and the second extending portion 27b are also formed is larger than the width from the first side face 24a to the second side face 24b in the x-direction and smaller than the width of the semiconductor substrate 8 in the x-direction.

In the optical semiconductor device 100 of Embodiment 4, the heater layer 3a and the heater layer 3b are provided so as to interpose the optical waveguide layer 2, whereby the optical waveguide layer 2 can be heated from the side of the first face 23a and the side of the second face 23b of the optical waveguide layer 2 through the cladding layer 1. Therefore, the optical semiconductor device 100 of Embodiment 4 can control the temperature of the optical waveguide layer 2 more efficiently than the optical semiconductor device 100 of Embodiment 3 in which the heater layer 3 is present only on the side of the first face 23a of the optical waveguide layer 2. Furthermore, the optical semiconductor device 100 of Embodiment 4 can control the temperature of the optical waveguide layer 2 more efficiently than the optical semiconductor device 100 of Embodiment 1 in which the heater layer 3 is present only on the side of the second face 23b of the optical waveguide layer 2. Accordingly, the optical semiconductor device 100 of Embodiment 4 can control the phase of the incident light propagating through the optical waveguide layer 2 more efficiently than the optical semiconductor device 100 of Embodiment 1 and the optical semiconductor device 100 of Embodiment 3.

As described above, the optical semiconductor device 100 of Embodiment 4 is provided with the semiconductor substrate 8 and the semiconductor structure part 30 including the optical waveguide layer 2 that is formed on the semiconductor substrate 8. The semiconductor structure part 30 includes the cladding layer 1b connected to the first face 23a that is the face on the side of the semiconductor substrate, and to the second face 23b that is the face on the opposite side of the semiconductor substrate 8, in the optical waveguide layer 2, and the heater layers 3a and 3b made of a semiconductor material to heat the optical waveguide layer 2 from the side of the first face and the side of the second face of the optical waveguide layer 2 through the cladding layer 1b. The heater layer 3a on the side of the first face is referred to as a first heater layer, and the heater layer 3b on the side of the second face is referred to as a second heater layer. The semiconductor structure part 30 includes the first side face 24a and the second side face 24b opposed to each other with the optical waveguide layer 2 interposed therebetween, and the first end face 26a and the second end face 26b that intersect with the extending direction of the optical waveguide layer 2 and are opposed to each other. The first heater layer (heater layer 3a) includes the first extending portion 25a extending from the first side face 24a on the side of the first end face in the semiconductor structure part 30 in the direction away from the optical waveguide layer 2 and the second extending portion 25b extending from the second side face 24b on the side of the second end face in the semiconductor structure part 30 in the direction away from the optical waveguide layer 2. A power supply electrode 5b is provided as the first electrode on the first extending portion 25a of the first heater layer (heater layer 3a), and a ground electrode 6b is provided as the second electrode on the second extending portion 25b of the first heater layer (heater layer 3a). A power supply electrode 5a is provided as a third electrode on the side of the first end face in the second heater layer (heater layer 3b), and a ground electrode 6a is provided as a fourth electrode on the side of the second end face in the second heater layer (heater layer 3b). With this configuration, the optical semiconductor device 100 of Embodiment 4 includes the optical waveguide layer 2 and the heater layers 3a and 3b made of a semiconductor material for heating the optical waveguide layer 2 from the side of the first face and the side of the second face of the optical waveguide layer 2 through the cladding layer 1b, and the semiconductor structure part 30 including the heater layers 3a and 3b can be formed, so that the conventional semiconductor structure part and the heater layers can be continuously formed, and the manufacturing period of time can be shortened more than before.

### Embodiment 5

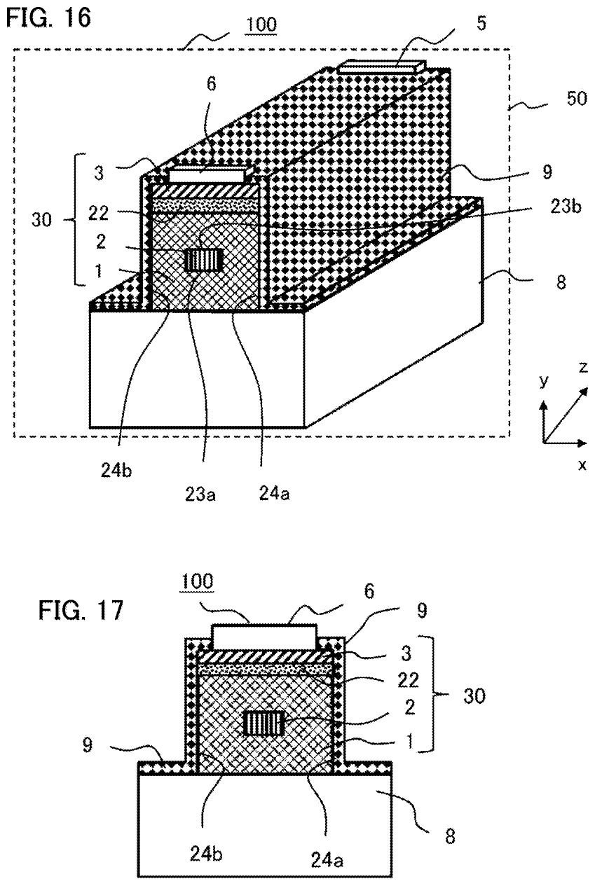

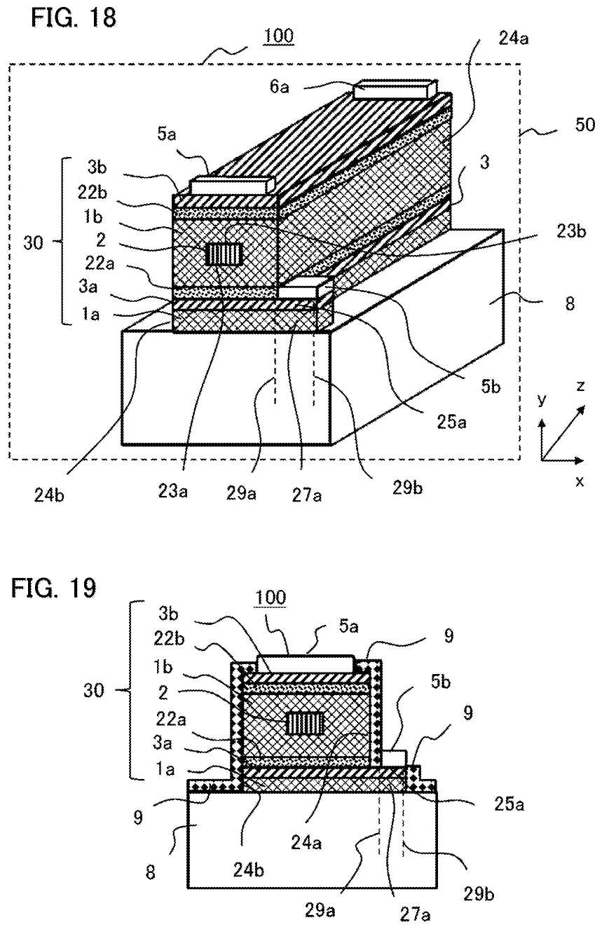

FIG. 16 is a perspective view showing an optical semiconductor device according to Embodiment 5, and FIG. 17 is a diagram showing an end face of the optical semiconductor device of FIG. 16. FIG. 18 is a perspective view showing another optical semiconductor device according to Embodiment 5, and FIG. 19 is a diagram showing an end face of the optical semiconductor device of FIG. 18. A phase adjuster 50, which is an example of the optical semiconductor device 100 of Embodiment 5, is different from the optical semiconductor devices 100 of Embodiment 1 to Embodiment 4 in that the semiconductor structure part 30 includes an electron barrier layer 22 or electron barrier layers 22a and 22b for suppressing movement of electrons from the heater layer 3 or the heater layers 3a and 3b to the side of the optical waveguide layer on the side of the heater layer between the heater layer 3 or heater layers 3a and 3b and the optical waveguide layer 2.

FIG. 16 and FIG. 17 illustrate an example in which the electron barrier layer 22 is added to the optical semiconductor device 100 of Embodiment 1. FIG. 18 and FIG. 19 illustrate an example in which the electron barrier layers 22a and 22b are added to the optical semiconductor device 100 of Embodiment 4. Note that, in FIG. 18, the insulating film 9 is omitted, and in FIG. 19, the second extending portion 25b of the heater layer 3a, the second extending portion 27b of the cladding layer 1a, and the ground electrode 6b that are disposed in the second side face 24b on the side of the second end face 26b are omitted.

The electron barrier layers 22, 22a, and 22b are made of a material having lower electron mobility than the cladding layers 1 and 1b, such as AlGaInAs. In the optical semiconductor device 100 of Embodiment 5, the electron barrier layer 22 or the electron barrier layers 22a and 22b can suppress a current that leaks to the cladding layer 1 or 1b, so that the heat can be efficiently generated from the heater layer 3 and the refractive index of the optical waveguide layer 2 can be efficiently changed. Therefore, the optical semiconductor device 100 of Embodiment 5 can control the phase of the light incident on the optical waveguide layer 2 more efficiently than the optical semiconductor devices 100 of Embodiment 1 to Embodiment 4. In particular, in a case where the phase adjuster 50 and the other optical element are integrated on the semiconductor substrate 8 as shown in Embodiment 6 to be described later, a voltage may be applied between an electrode of the other optical element and the power supply electrode 5 connected to the heater layer 3. Also in this case, the current that leaks to the cladding layer 1 or 1b can be suppressed by the electron barrier layer 22 or the electron barrier layers 22a and 22b.

The optical semiconductor device 100 of Embodiment 5 is provided with the same structure as the optical semiconductor devices 100 of Embodiment 1 to Embodiment 4 except that the electron barrier layer 22 or the electron barrier layers 22a and 22b for suppressing the movement of electrons from the heater layer 3 or the heater layers 3a and 3b to the side of the optical waveguide layer are added on the side of the heater layer between the heater layer 3 or the heater layers 3a and 3b and the optical waveguide layer 2 in the semiconductor structure part 30, and thus the optical semiconductor device 100 of Embodiment 5 exhibits the same effect as in the optical semiconductor device 100 of Embodiment 1 to Embodiment 4.

Note that, in Embodiment 5, an example is shown in which the power supply electrodes 5, 5a, and 5b and the ground electrodes 6, 6a, and 6b, which are electrodes connected to the heater layer 3 or the heater layer 3a and 3b of the phase adjuster 50 for the energization, are located on the negative side in the z-direction and the positive side in the z-direction, respectively. However, as in Embodiment 1, the ground electrodes 6, 6a, and 6b and the power supply electrodes 5, 5a, and 5b may be arranged on the negative side in the z-direction and the positive side in the z-direction, respectively.

### Embodiment 6

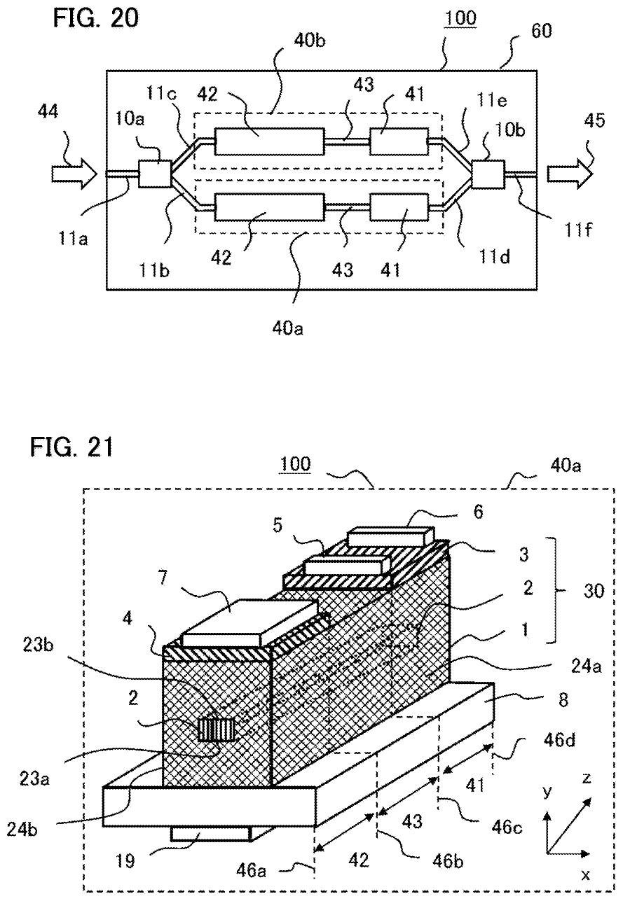

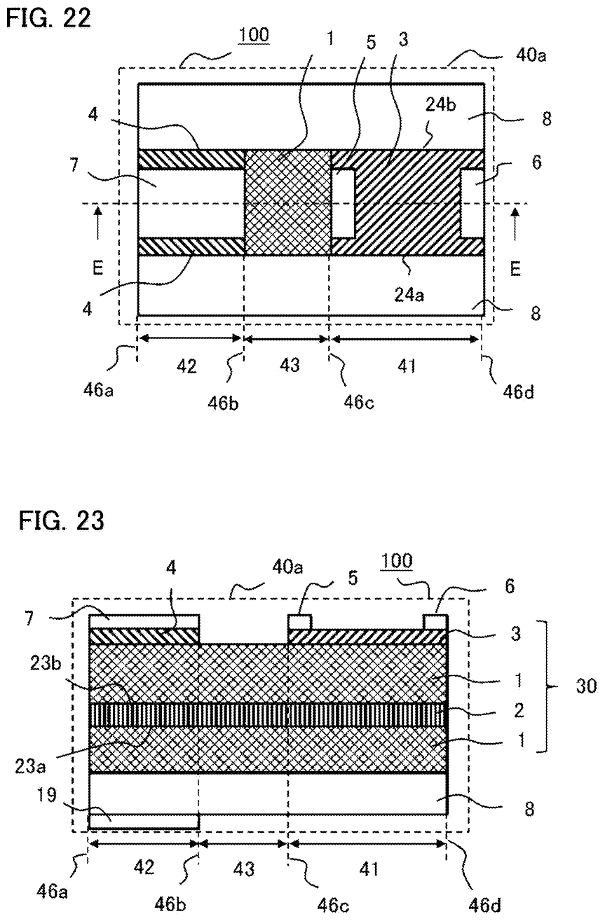

FIG. 20 is a diagram showing an optical semiconductor device according to Embodiment 6, and FIG. 21 is a perspective view showing an optical processing section of FIG. 20. FIG. 22 is a plan view of the optical processing section of FIG. 20, and FIG. 23 is a cross-sectional view taken along a broken line E-E in FIG. 22. In Embodiment 6, a modulator 60 and optical processing sections 40a and 40b, which are part of the modulator 60, will be described as an example of the optical semiconductor device 100. The modulators 60 is a Mach-Zehnder modulator. The modulators 60 includes the optical processing sections 40a and 40b, multi-mode interference (MMI) couplers (optical multiplexer/demultiplexer) 10a and 10b, and waveguides 11a, 11b, 11c, 11d, 11e, and 11f. The optical processing sections 40a and 40b have functions of the respective arms for the Mach-Zehnder modulator. Each of the optical processing sections 40a and 40b includes a modulating part 42, a separating part 43, and a phase adjusting part 41.

Input light 44 is input to the waveguide 11a. The input light 44 is demultiplexed by the MMI coupler 10a, propagates through the waveguides 11b and 11c, and is input to the optical processing sections 40a and 40b. Signal light output from the optical processing section 40a is input to the MMI coupler 10b via the waveguide 11d. Signal light output from the optical processing section 40b is input to the MMI coupler 10b via the waveguide 11e. The MMI coupler 10b multiplexes the signal light from the optical processing section 40a and the signal light from the optical processing section 40b, and outputs output light 45 from the waveguide 11f.

Each of the optical processing sections 40a and 40b has a structure in which the modulating part 42, the separating part 43, and the phase adjusting part 41 are connected in this order from the upstream side where the input light 44 is input. The phase adjuster 50 of Embodiment 1 to Embodiment 5 can be applied to the phase adjusting part 41. FIG. 21 to FIG. 23 illustrate an example in which the phase adjuster 50 of Embodiment 1 is applied to the phase adjusting part 41. In FIG. 21 to FIG. 23, the insulating film 9 is omitted. In FIG. 21 to FIG. 23, the part from a broken line 46a to a broken line 46b is the modulating part 42, the part from the broken line 46b to a broken line 46c is the separating part 43, and the part from the broken line 46c to a broken line 46d is the phase adjusting part 41. In the phase adjusting part 41, the semiconductor structure part 30 including the optical waveguide layer 2 is formed on the semiconductor substrate 8. The semiconductor structure part 30 includes the optical waveguide layer 2, the cladding layer 1 connected to the first face 23a that is the face on the side of the semiconductor substrate, and to the second face 23b that is the face on the opposite side of the semiconductor substrate 8, in the optical waveguide layer 2, and the heater layer 3 made of a semiconductor material to heat the optical waveguide layer 2 from the side of the second face 23b of the optical waveguide layer 2 through the cladding layer 1. The heater layer 3 is provided with two electrodes for energizing the heater layer 3, i.e., the power supply electrode 5 and the ground electrode 6.

In the modulating part 42, a semiconductor structure part including the optical waveguide layer 2 is formed on the semiconductor substrate 8. The semiconductor structure part of the modulating part 42 has a structure in which the heater layer 3 in the semiconductor structure part 30 of the phase adjusting part 41 is replaced with the contact layer 4. A bias electrode 7 is formed on the top surface of the contact layer 4, and a ground electrode 19 is formed on the rear surface that is the surface opposite side of the top surface of the semiconductor substrate 8. In the separating part 43, a semiconductor structure part including the optical waveguide layer 2 is formed on the semiconductor substrate 8. The semiconductor structure part of the separating part 43 has a structure in which the heater layer 3 in the semiconductor structure part 30 of the phase adjusting part 41 is not formed. The cladding layer 1 and the optical waveguide layer 2 are integrally formed in the modulating part 42, the separating part 43, and the phase adjusting part 41. The heater layer 3 of the phase adjusting part 41 and the contact layer 4 of the modulating part 42 are integrally formed as a single layer and are separated in the separating part 43.

The cladding layer 1, the optical waveguide layer 2, the heater layer 3, and the contact layer 4 are stacked by a manufacturing apparatus using, for example, a metalorganic vapor phase epitaxy (MOVPE) method or the like, and are etched by a dry etching apparatus to be formed in the mesa shape. The dry etching apparatus is, for example, an inductively coupled plasma (ICP) etching apparatus, a reactive ion etching (RIE) apparatus, or the like.

The semiconductor substrate 8 is, for example, an InP substrate. The material of the optical waveguide layer 2 is, for example, a material having a wavelength of the absorption edge on the shorter wavelength side than the incident light oscillation wavelength, and the optical waveguide layer 2 is made of, for example, an InGaAsP-based crystal. The optical waveguide layer 2 has a photoluminescence (PL) wavelength of about 1.3 μm.

The cladding layer 1 is made of, for example, InP, and has a function of confining light such as laser light propagating through the optical waveguide layer 2. The heater layer 3 and the contact layer 4 are made of, for example, a semiconductor material such as InGaAs, and are integrally formed by a manufacturing apparatus such as MOVPE used for forming the cladding layer 1 and the optical waveguide layer 2. Each material of the power supply electrode 5 and the ground electrode 6 connected to the heater layer 3, the bias electrode 7 connected to the contact layer 4, and the ground electrode 19 connected to the rear surface of the semiconductor substrate 8 is a conductive material such as Au.

In the case where the modulator 60, which is the Mach-Zehnder modulator, is operated, electric power is supplied by causing a current to flow from the power supply electrode 5 to the ground electrode 6 in the phase adjusting part 41 in the optical processing sections 40a and 40b. The light propagating through the optical processing section 40a changes in phase in accordance with the signal applied to the bias electrode 7 and the ground electrode 19 in the phase adjusting part 41 of the optical processing section 40a and is adjusted in phase by the heat from the heater layer 3 of the phase adjusting part 41. Similarly, the light propagating through the optical processing section 40b changes in phase in accordance with the signal applied to the bias electrode 7 and the ground electrode 19 in the phase adjusting part 41 of the optical processing section 40b and is adjusted in phase by the heat from the heater layer 3 of the phase adjusting part 41. As described above, a difference in phase between the light signal output from the optical processing section 40a and the light signal output from the optical processing section 40b is mx. Here, m is an integer, and when m is 0 or an even number, the two light signals strengthen each other, and light with high light intensity is output, and when m is an odd number, the two light signals cancel each other, and light with low light intensity is output. For example, the modulator 60 performs the modulation in such a manner that a state in which light with high light intensity is output is set to 1 in the digital signal and a state in which light with low light intensity is output is set to 0 in the digital signal.

When a reverse bias voltage and a signal voltage that are predetermined are applied between the bias electrode 7 and the ground electrode 19 in the modulating part 42, the phase of the light after passing through the modulating part 42 changes. A first voltage applied between the bias electrode 7 and the ground electrode 19 in the modulating part 42 of the optical processing section 40a is different from a second voltage applied between the bias electrode 7 and the ground electrode 19 in the modulating part 42 of the optical processing section 40b. For example, in the case where the first voltage is applied in the modulating part 42 of the optical processing section 40a so that the difference in phase of light before and after passing through the modulating part 42 satisfies nπ (n is 0 or an even number) and the second voltage is applied in the modulating part 42 of the optical processing section 40b so that the difference in phase of light before and after the passing through the modulating part 42 satisfies nπ (n is 0 or an even number), the output light 45 multiplexed by the MMI coupler 10b is output as the light with high light intensity. In the case where the first voltage is applied in the modulating part 42 of the optical processing section 40a so that the difference in phase of light before and after passing through the modulating part 42 satisfies kπ (k is an odd number) and the second voltage is applied in the modulating part 42 of the optical processing section 40b so that the difference in phase of light before and after passing through the modulating part 42 satisfies nπ (n is 0 or an even number), the light 45 multiplexed by the MMI coupler 10b is output as the light with low light intensity. By applying the first voltage and the second voltage, that is, the first voltage and second voltage that are predetermined, in the modulating part 42 of the optical processing section 40a and the modulating part 42 of the optical processing section 40b, respectively, the modulator 60 can output the output light 45 in which the input light 44 is modulated.

The light that has passed through the optical waveguide layer 2 of the modulating part 42 of each of the optical processing sections 40a and 40b passes through the optical waveguide layer 2 in the separating part 43 and enters the phase adjusting part 41. When power is supplied to the heater layer 3 in the phase adjusting part 41, the temperature of the optical waveguide layer 2 of the phase adjusting part 41 is adjusted in accordance with the magnitude of the power. Thus, the refractive index of the optical waveguide layer 2 changes, and as a result, the phase of light passing through the optical waveguide layer 2 of the phase adjusting part 41 changes. As described above, the phase of the light incident on the optical semiconductor device 100 can be adjusted by controlling the magnitude of the current supplied to the heater layer 3. The modulator 60, which is the optical semiconductor device 100 of Embodiment 6, can adjust the phases of light of the two arms, that is, the phases of light of the optical processing sections 40a and 40b with high accuracy by the phase adjusting part 41, and can improve the extinction ratio of the output light 45 in which the light of the two arms is multiplexed.

The modulating parts 42 of the optical processing sections 40a and 40b are controlled such that the light after the multiplexing is modulated by the first voltage and the second voltage, but there are cases where an ideal phase difference may not be achieved between the output light from the two modulating parts 42 and a deviation may occur. This deviation is caused by an optical path difference that occurs between the optical processing sections 40a and 40b due to dimensional variations in manufacturing. The phase change processing by the modulating part 42 can also be referred to as pre-modulation processing. The phase adjusting parts 41 of the optical processing sections 40a and 40b adjust the deviation of the phase from the phase of the ideal state, that is, the phase deviation of the light, which is caused by the phase change processing performed by the modulating parts 42. The modulator 60, which is the optical semiconductor device 100 of Embodiment 6, adjusts the phase deviation in the modulating parts 42 by the phase adjusting parts 41 in the two optical processing sections 40a and 40b, whereby the output light 45 of the modulation signal with less distortion can be outputted after the multiplexing in the MMI coupler 10b.

In the optical semiconductor device 100 of Embodiment 6, the contact layer 4 of the phase adjusting part 41 and the heater layer 3 of the modulating part 42 are made of the same semiconductor material. Therefore, different from the optical semiconductor device provided with the conventional semiconductor structure part in which the heater layer and the contact layer cannot be formed in the same process because of the difference in the material of the heater layer and the material of the contact layer, the optical semiconductor device can be manufactured in a short period of time because the heater layer 3 and the contact layer 4 can be formed in the same process. Further, in the optical semiconductor device 100 of Embodiment 6, since the heater layer 3 and the contact layer 4 can be formed in the same process, a film forming apparatus for forming a metal material of the conventional heater layer can be eliminated, so that the manufacturing cost can be reduced. In the optical semiconductor device 100 of Embodiment 6, since the heater layer 3 is made of a semiconductor material, it is possible to improve the processing accuracy of the heater layer 3 by performing dry etching or the like in the semiconductor process and to reduce the deviation of the resistance value due to the variation in the shape of the heater layer 3.

Since the optical semiconductor device 100 of Embodiment 6 includes optical clement parts such as the phase adjusting part 41 that is operated only with the electrodes for energizing the heater layer 3 and the modulating part 42 in which a voltage is applied between electrodes different from the electrodes for energizing the heater layer 3, the conductivity type, i.e., n-type or p-type, of the cladding layer 1 of the phase adjusting part 41 is made the same as the conductivity type of the optical clement part such as the modulating part 42. For example, in the case where the semiconductor substrate 8 is an n-type InP substrate, the cladding layer 1 below the optical waveguide layer 2, that is, the lower layer on the side of the semiconductor substrate 8, is set to be n-type, the upper cladding layer 1 covering the surface of the optical waveguide layer 2 (the surface on the positive side in the y-direction, the side surface on the positive side in the x-direction, the side surface on the negative side in the x-direction) is set to be p-type, and the contact layer 4 and the heater layer 3 are set to be p-type. Furthermore, in the case where the semiconductor substrate 8 is a p-type InP substrate, the cladding layer 1 below the optical waveguide layer 2, that is, the lower layer on the side of the semiconductor substrate 8, is set to be p-type, the upper cladding layer 1 covering the surfaces of the optical waveguide layer 2 (the surface on the positive side in the y-direction, the side face on the positive side in the x-direction, and the side face on the negative side in the x-direction) is set to be n-type, and the contact layer 4 and the heater layer 3 are set to be n-type.

Note that, in Embodiment 6, although the power supply electrode 5 and the ground electrode 6, which are connected to the heater layer 3 of the phase adjusting part 41 for the energization, are disposed on the negative side in the z-direction and the positive side in the z-direction, respectively, however, as in Embodiment 1, the ground electrode 6 and the power supply electrode 5 may be arranged on the negative side in the z-direction and the positive side in the z-direction, respectively.

As described above, the optical semiconductor device 100 of Embodiment 6 includes the phase adjusting part 41 in which the semiconductor substrate 8 and the semiconductor structure part 30 including the optical waveguide layer 2 that is formed on the semiconductor substrate 8 are provided. The optical semiconductor device 100 of Embodiment 6 further includes the modulating part 42 that is formed on the semiconductor substrate 8, is optically coupled to the optical waveguide layer 2 of the phase adjusting part 41, and modulates the input light 44 to be input. The semiconductor structure part 30 includes the cladding layer 1 connected to the first face 23a that is the face on the side of the semiconductor substrate, and to the second face 23b that is the face on the opposite side of the semiconductor substrate 8, in the optical waveguide layer 2, and the heater layer 3 made of a semiconductor material to heat the optical waveguide layer 2 from the side of the second face of the optical waveguide layer 2 through the cladding layer 1. The modulating part 42 includes the optical waveguide layer 2 extending from a phase adjusting part 41, the cladding layer 1 connected to the first face 23a that is the face on the semiconductor substrate side, and to the second face 23b that is the face opposite to the semiconductor substrate 8, in the optical waveguide layer 2, and the contact layer 4, which is formed on the surface farther from the semiconductor substrate 8 than the second face 23b of the optical waveguide layer 2 in the cladding layer 1, and which is made of the same material as the heater layer 3. With this configuration, in the optical semiconductor device 100 of Embodiment 6, the phase adjusting part 41 includes the optical waveguide layer 2 and the heater layer 3 made of a semiconductor material for heating the optical waveguide layer 2 from the side of the second face of the optical waveguide layer 2 through the cladding layer 1, and the semiconductor structure part 30 including the heater layer 3 can be formed, so that the conventional semiconductor structure part and the heater layer can be continuously formed, and the manufacturing period of time can be shortened more than before.

Note that, although various exemplary embodiments and examples are described in the present application, various features, aspects, and functions described in one or more embodiments are not inherent in a particular embodiment and can be applicable alone or in their various combinations to each embodiment. Accordingly, countless variations that are not illustrated are envisaged within the scope of the art disclosed herein. For example, the case where at least one component is modified, added or omitted, and the case where at least one component is extracted and combined with a component in another embodiment are included.

### DESCRIPTION OF REFERENCE NUMERALS AND SIGNS

1, 1a, 1b: cladding layer, 2: optical waveguide layer, 3, 3a, 3b: heater layer, 4: contact layer, 5, 5a, 5b: power supply electrode, 6, 6a, 6b: ground electrode, 8: substrate, 22, 22a, 22b: electron-barrier layer, 23a: first face, 23b: second face, 24a: first side face, 24b: second side face, 25a: first extending portion, 25b: second extending portion, 26a: first end face, 26b: second end face, 30: semiconductor structure part, 41: phase adjusting part, 42: modulating part, 100: optical semiconductor device

1. An optical semiconductor device comprising:
a semiconductor substrate; and
a semiconductor structure part including an optical waveguide layer that is formed on the semiconductor substrate, wherein
the semiconductor structure part includes a cladding layer connected to a first face that is a face on a side of the semiconductor substrate, and to a second face that is a face on an opposite side of the semiconductor substrate, in the optical waveguide layer,
a heater layer is provided on a side of the first face in the optical waveguide layer, and is made of a semiconductor material to heat the optical waveguide layer from the side of the first face in the optical waveguide layer through the cladding layer,
first side face and a second side face that are opposed to each other with the optical waveguide layer interposed therebetween and a first end face and a second end face that intersect with an extending direction of the optical waveguide layer and are opposed to each other,
the heater layer includes a first extending portion extending from the first side face on a side of the first end face in the semiconductor structure part in a direction away from the optical waveguide layer and a second extending portion extending from the second side face on a side of the second end face in the semiconductor structure part in a direction away from the optical waveguide layer, and
a first electrode is provided on the first extending portion, and a second electrode is provided on the second extending portion.

2.-3. (canceled)

4. An optical semiconductor device comprising:
a semiconductor substrate; and
a semiconductor structure part including an optical waveguide layer that is formed on the semiconductor substrate, wherein
the semiconductor structure part includes a cladding layer connected to a first face that is a face on a side of the semiconductor substrate, and to a second face that is a face on an opposite side of the semiconductor substrate, in the optical waveguide layer, and
a heater layer is provided on a side of the first face and a side of the second face in the optical waveguide layer, and is made of a semiconductor material to heat the optical waveguide layer from the side of the first face and from the side of the second face in the optical waveguide layer through the cladding layer
a first side face and a second side face that are opposed to each other with the optical waveguide layer interposed therebetween,
a first end face and a second end face that intersect with an extending direction of the optical waveguide layer and are opposed to each other,
the heater layer on the side of the first face is referred to as a first heater layer, and the heater layer on the side of the second face is referred to as a second heater layer,
the first heater layer includes a first extending portion extending from the first side face on a side of the first end face in the semiconductor structure part in a direction away from the optical waveguide layer and a second extending portion extending from the second side face on a side of the second end face in the semiconductor structure part in a direction away from the optical waveguide layer,
a first electrode is provided on the first extending portion,
a second electrode is provided on the second extending portion,
a third electrode is provided on the side of the first end face in the second heater layer, and
a fourth electrode is provided on the side of the second end face in the second heater layer.

5. The optical semiconductor device according to claim 1, wherein the semiconductor structure part further includes an electron barrier layer on a side of the heater layer between the heater layer and the optical waveguide layer, the electron barrier layer suppressing movement of electrons from the heater layer to the optical waveguide layer.

6. The optical semiconductor device according to claim 4, wherein the semiconductor structure part further includes an electron barrier layer on a side of the heater layer between the heater layer and the optical waveguide layer, the electron barrier layer suppressing movement of electrons from the heater layer to the optical waveguide layer.

7. The optical semiconductor device according to claim 5, wherein the electron barrier layer has a lower electron mobility than the heater layer.

8. The optical semiconductor device according to claim 6, wherein the electron barrier layer has a lower electron mobility than the heater layer.

9. The optical semiconductor device according to claim 1, wherein the heater layer has a resistivity lower than that of the cladding layer.

10. The optical semiconductor device according to claim 4, wherein the heater layer has a resistivity lower than that of the cladding layer.

11. An optical semiconductor device comprising:
a phase adjusting part to which the optical semiconductor device according to claim 1 is applied; and
a modulating part that is formed on the semiconductor substrate, is optically coupled to the optical waveguide layer of the phase adjusting part, and modulates input light to be input.

12. An optical semiconductor device comprising:
a phase adjusting part to which the optical semiconductor device according to claim 4 is applied; and
a modulating part that is formed on the semiconductor substrate, is optically coupled to the optical waveguide layer of the phase adjusting part, and modulates input light to be input.

13. The optical semiconductor device according to claim 12, wherein
the modulating part includes the optical waveguide layer extending from the phase adjusting part,
a cladding layer connected to a first face that is a face on a side of the semiconductor substrate, and to a second face that is a face on an opposite side of the semiconductor substrate, in the optical waveguide layer, and
a contact layer formed on a surface of the cladding layer farther from the semiconductor substrate than the second face of the optical waveguide layer, the contact layer being made of a same material as the heater layer.

14. The optical semiconductor device according to claim 5, wherein the heater layer has a resistivity lower than that of the cladding layer.

15. The optical semiconductor device according to claim 7, wherein the heater layer has a resistivity lower than that of the cladding layer.

16. The optical semiconductor device according to claim 6, wherein the heater layer has a resistivity lower than that of the cladding layer.

17. The optical semiconductor device according to claim 8, wherein the heater layer has a resistivity lower than that of the cladding layer.

18. An optical semiconductor device comprising:
a phase adjusting part to which the optical semiconductor device according to claim is applied; and
a modulating part that is formed on the semiconductor substrate, is optically coupled to the optical waveguide layer of the phase adjusting part, and modulates input light to be input.

19. An optical semiconductor device comprising:
a phase adjusting part to which the optical semiconductor device according to claim 7 is applied; and
a modulating part that is formed on the semiconductor substrate, is optically coupled to the optical waveguide layer of the phase adjusting part, and modulates input light to be input.

20. An optical semiconductor device comprising:
a phase adjusting part to which the optical semiconductor device according to claim 9 is applied; and
a modulating part that is formed on the semiconductor substrate, is optically coupled to the optical waveguide layer of the phase adjusting part, and modulates input light to be input.

21. An optical semiconductor device comprising:
a phase adjusting part to which the optical semiconductor device according to claim 6 is applied; and
a modulating part that is formed on the semiconductor substrate, is optically coupled to the optical waveguide layer of the phase adjusting part, and modulates input light to be input.

22. An optical semiconductor device comprising:
a phase adjusting part to which the optical semiconductor device according to claim 8 is applied; and
a modulating part that is formed on the semiconductor substrate, is optically coupled to the optical waveguide layer of the phase adjusting part, and modulates input light to be input.
